(19) United States
(12) Patent Application Publication
(10) Pub. No.: US 2010/0270067 A1
(43) Pub. Date: Oct. 28, 2010

(54) PRINTED CIRCUIT BOARD AND METHOD OF MANUFACTURING THE SAME

(75) Inventors: Jin-Won CHOI, Yongin-si (KR); Tae-Joon Chung, Seoul (KR); Dong-Gyu Lee, Suwon-si (KR); Seok-Hwan Ahn, Suwon-si (KR); Seung-Wan Kim, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/611,558

(22) Filed: Nov. 3, 2009

(30) Foreign Application Priority Data
Apr. 25, 2009 (KR) 10-2009-0036420

(51) Int. Cl. H05K 1/11; H05K 3/10

(52) U.S. Cl. 174/267; 29/846

(57) ABSTRACT

A printed circuit board and a method of manufacturing the printed circuit board are disclosed. In accordance with an embodiment of the present invention, the method includes providing a substrate having a pad formed thereon, forming a resist on the substrate, in which the resist has an opening formed therein such that the pad is exposed, forming a metal post inside the opening such that the metal post is electrically connected to the pad, forming a through-hole in the resist by removing a portion of the resist such that the through-hole surrounds the metal post, and forming a solder layer inside the through-hole and on an upper surface of the metal post so as to cover an exposed surface of the metal post.

### CROSS-REFERENCE TO RELATED APPLICATIONS

This application claims the benefit of Korean Patent Application No. 10-2009-0036420, filed with the Korean Intellectual Property Office on Apr. 27, 2009, the disclosure of which is incorporated herein by reference in its entirety.

### BACKGROUND

1. Technical Field

The present invention relates to a printed circuit board and a method of manufacturing the printed circuit board.

2. Description of the Related Art

In recent years, there has been an increasing demand for electronic products, such as computers, telecommunication devices, mobile communication devices and high-end consumer products, which have higher electrical performance, smaller-size/higher-density, low power consumption, multifunctionality, high-speed signal processing and permanent product reliability. Accordingly, the I/O density of an electronic component package, which is an essential part required for these electronic products, has also increased.

Today, the flip-chip technology is increasingly and widely applied to the process of mounting electronic components on a printed circuit board since the flip-chip technology may minimize a distance between the electronic components and the printed circuit board and thus improve the electrical property.

In the conventional technology, a solder bump, which is made of solder paste, is formed on an electrode of an electronic component and a pad of a printed circuit board, and then the electronic component is mounted on the printed circuit board by coupling the solder bumps to each other through a reflow process.

In the conventional technology, however, when flip-chip coupling the solder bumps to each other, diffusion may occur between the solder bumps due to the reflow process so that the overall height of the solder bumps may be decreased. Also, when the coupling pressure is excessive, the solder bumps may be tilted toward one side so that a short circuit may occur between the adjacent solder bumps. Moreover, since the heights of the solder bumps are not made uniform, defective interconnection between the electronic component and the printed circuit board may be occurred. Also, the thermal and electrical conductivity may be lowered due to the high resistance of the solder bumps.

### SUMMARY

The present invention provides a printed circuit board and a method of manufacturing the printed circuit board that can prevent possible height reduction of a bump and a short circuit between the adjacent bumps, form the bump in a uniform height, and improve thermal and electrical conductivity.

An aspect of the present invention provides a method of manufacturing a printed circuit board that includes providing a substrate having a pad formed thereon, forming a resist on the substrate, in which the resist has an opening formed therein such that the pad is exposed, forming a metal post inside the opening such that the metal post is electrically connected to the pad, forming a through-hole in the resist by removing a portion of the resist such that the through-hole surrounds the metal post, and forming a solder layer inside the through-hole and on an upper surface of the metal post so as to cover an exposed surface of the metal post.

The forming of the through-hole can be performed by a laser.

The forming of the metal post can be performed by way of plating.

Prior to the forming of the metal post, the method can further include forming a seed layer on the pad.

After the forming of the solder layer, the method can further include flattening an upper surface of the solder layer such that the upper surface of the solder layer becomes level.

Another aspect of the invention provides a printed circuit board that includes a substrate, which has a pad formed therein, a metal post, which is formed on the pad such that the metal post is electrically connected to the pad, and a solder layer, which is formed on a side of the metal post and an upper surface of the metal post so as to cover an exposed surface of the metal post.

The printed circuit board can further include a seed, which is interposed between the pad and the metal post.

An upper surface of the solder layer can be a planar surface.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating an embodiment of a method of manufacturing a printed circuit board in accordance with an aspect of the present invention.

FIGS. 2 to 10 show the process flow of an embodiment of the method of manufacturing a printed circuit board in accordance with an aspect of the present invention.

FIGS. 11 to 14 show the process flow of a portion of a process for another embodiment of the method of manufacturing a printed circuit board in accordance with an aspect of the present invention.

FIG. 15 is a cross-sectional view illustrating an embodiment of a printed circuit board in accordance with another aspect of the present invention.

### DETAILED DESCRIPTION

A printed circuit board and a method of manufacturing the printed circuit board according to certain embodiments of the present invention will be described below in more detail with reference to the accompanying drawings. Those components that are the same or are in correspondence are rendered the same reference numeral regardless of the figure number, and redundant descriptions are omitted.

It is to be noted that forming of components encompasses not only the direct physical engaging between the components but also the engaging of the components with another element interposed in between such that the components are in contact with the other element.

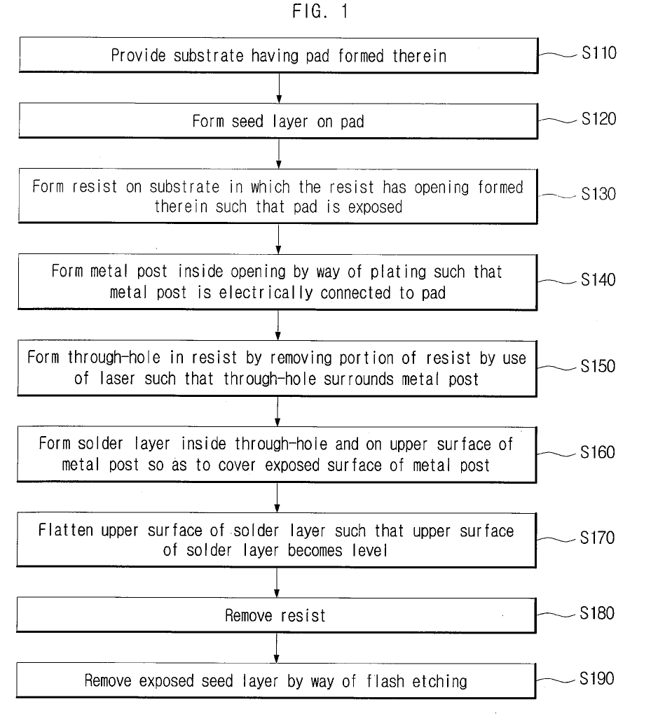

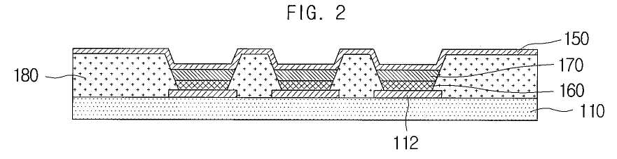

FIG. 1 is a flowchart illustrating an embodiment of a method of manufacturing a printed circuit board 100 in accordance with an aspect of the present invention. FIGS. 2 to 10 show the process flow of an embodiment of the method of manufacturing the printed circuit board 100 in accordance with an aspect of the present invention.

In accordance with the present embodiment, as illustrated in FIGS. 1 to 10, the method of manufacturing the printed circuit board 100 includes providing a substrate 110 having a pad 112 formed thereon, forming a resist 120′ on the substrate 110, in which the resist 120′ has an opening 122 formed therein such that the pad 112 is exposed, forming a metal post 130 inside the opening 122 such that the metal post 130 is electrically connected to the pad 112, forming a through-hole 124 in the resist 120′ by removing a portion of the resist 120′ such that the through-hole surrounds the metal post, and forming a solder layer 140 inside the through-hole and an upper surface of the metal post so as to cover an exposed surface of the metal post.

In accordance with the present embodiment, a bump is constituted by the metal post 130 and the solder layer 140 that surrounds the metal post 130. Accordingly, when an electronic component and the printed circuit board 100 are coupled together through the flip-chip process, the metal post 130 may function as a core that maintains its shape, and only the solder layer 140, which has a relatively low melting point, may be reflowed. Therefore, the height of the bump can be prevented from possible height reduction, and a short circuit between the adjacent bumps can be prevented from occurring when the bumps are tilted toward one side.

Furthermore, the metal post 130, unlike the solder layer 140, is made of a low resistance material such as copper, so that thermal and electrical conductivity can be improved. As a result, as compared with a bump that is formed by using the conventional solder paste, signal transmission of an electronic component package, heat dissipation and warpage properties can be improved.

Moreover, the metal post 130 and the solder layer 140 can be formed by filling the opening 122 and the through-hole 124 formed in the resist 120′, so that the height of bumps can be made uniform when a plurality of bumps are formed. Thus, defective interconnection between the printed circuit board 100 and the electronic components caused by a height difference between the plurality of bumps can be prevented.

In addition to the above, unlike a conventional method in which a plurality of resists are used in order to form the opening 122 and the through-hole 124, it is possible that both the opening 122 and the through-hole 124 can be formed by using a single resist 120′, to form the metal post 130 and the solder layer 140. Therefore, the manufacturing process can be simplified and the manufacturing costs can be reduced.

Each of the processes will be described in more detail with reference to FIGS. 1 to 10 hereinafter.

First, as illustrated in FIG. 2, a substrate 110 having a pad 112 formed thereon is provided (S110). The substrate 110 can be made of a nonconductive substance, and the pad 112 is formed on the substrate 110. Moreover, a solder resist layer 180, of which a portion corresponding to the pad 112 is removed, is formed on the substrate 110 such that the pad 112 is exposed. Then, a nickel layer 160 and a gold layer 170 can be successively formed on the pad 112. Additionally, a circuit pattern can be formed on the substrate 110 even though it is not illustrated in the drawings.

Next, as illustrated in FIG. 2, a seed layer 150 is formed on the pad 112 (S120). As described above, the seed layer 150 is formed on a surface of the substrate 110, on which the pad 112, the solder resist layer 180, the nickel layer 160 and the gold layer 170 are formed. Therefore, by forming the seed layer 150 on the gold layer 170 that is formed on the pad 112, the seed layer 150 is formed on the pad 112.

As such, before forming a metal post 130, the seed layer 150 can be formed on the pad 112, and then the metal post 130 can be formed by way of electroplating. Therefore, the rigidity of the metal post 130 can be improved, and at the same time, thermal and electrical conductivity can be further improved.

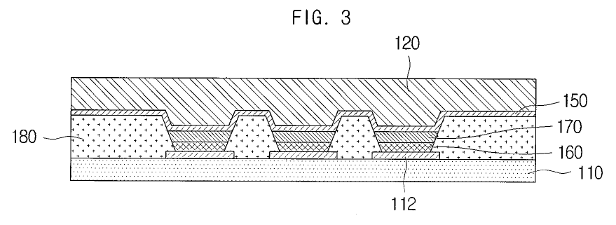

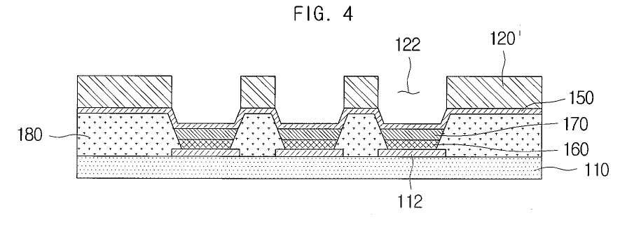

Next, as illustrated in FIGS. 3 and 4, a resist 120′, which has an opening 122 formed therein such that the pad 112 is exposed, is formed on the pad 110 (S130). To form the resist 120′, a photosensitive resist 120 is formed on the seed layer 150, and then the opening 122 is formed in the photosensitive resist 120 by way of photolithography. The processes will be further described below.

First, as illustrated in FIG. 3, the resist 120 is formed on the substrate 110 by forming the resist 120 on the seed layer 150. That is, the photosensitive resist 120 is formed on the seed layer 120. Then, as illustrated in FIG. 4, the opening 122 is formed in the photosensitive resist 120 by way of photolithography, to form the resist 120′. That is, a portion, corresponding to the position of the pad 112, of the resist 120′ is removed by exposing and developing the portion by use of ultraviolet rays. Thus, the opening 122 for exposing the pad 112, the nickel layer 160 and the gold layer 170 in order to form the metal post 130 later can be formed.

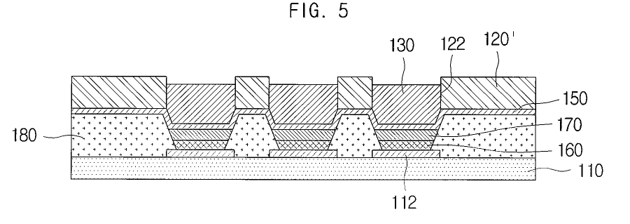

Next, as illustrated in FIG. 5, the metal post 130 is formed inside the opening 122 by way of plating such that the metal post 130 is electrically connected to the pad 112 (S140). By filling the inside of the opening 122 with a conductive material, such as copper, by way of plating, the metal post 130, which is electrically connected to the gold layer 170 formed on the pad 112, is formed.

As such, by forming the metal post 130 as a core of a bump, when electronic components and the printed circuit board 100 are coupled together through the flip-chip process, only the solder layer 140 is reflowed. Therefore, the height of the bumps can be prevented from possible height reduction, and a short circuit between the adjacent bumps can be prevented from occurring when the bumps are tilted toward one side.

Furthermore, the metal post 130 is made of a low resistance material such as copper so that thermal and electrical conductivity can be improved. Therefore, as compared with a bump that is formed by using the conventional solder paste, signal transmission of an electronic component package, heat dissipation and warpage properties can be improved.

As described above, the present processes are performed by electroplating. As a result, the rigidity of the metal post 130 can be improved, and at the same time, thermal and electrical conductivity can be further improved.

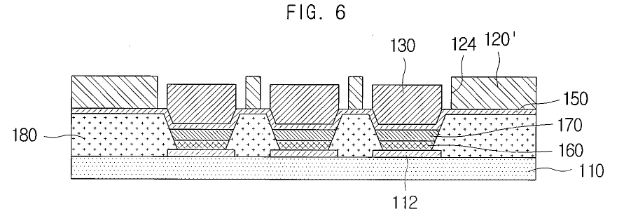

Next, as illustrated in FIG. 6, by removing a portion of the resist 120′ through the use of a laser, the through-hole 124 is formed in the resist 120′ such that the through-hole 124 surrounds the metal post 130 (S150). That is, a portion, surrounding the metal post 130, of the resist 120′ can be removed through the laser processing so that the through-hole 124 can be formed.

Accordingly, in a following process, the solder layer 140 can be formed by filling the through-hole 124 with solder, and thus a bump that is constituted by the metal post 130 and the solder layer 140 surrounding an exposed surface of the metal post 130 can be implemented.

In the present embodiment, unlike a conventional method in which an additional resist may be formed after removing the resist 120′ having the opening 122 formed therein in order to form the through-hole 124, the through-hole 124 can be formed by only removing a portion of the resist 120′ having the opening 122 formed therein, so that the manufacturing process can be simplified and the manufacturing costs can be reduced.

Furthermore, the metal post 130 and the solder layer 140 can be formed by filling the opening 122 and the through-hole 124, which have been formed through the processes S130 and S150, so that the height of bumps can be made uniform when a plurality of bumps are formed. Thus, defective interconnection between the printed circuit board 100 and the electronic components caused by a height difference between the plurality of bumps can be prevented.

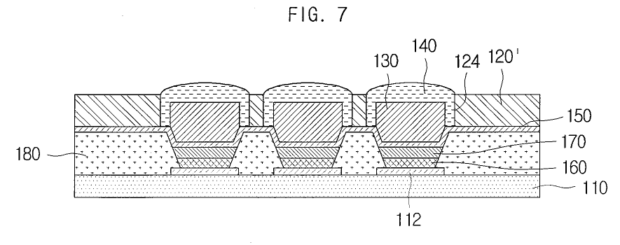

Next, as illustrated in FIG. 7, a solder layer 140 is formed inside the through-hole 124 and an upper surface of the metal post 130 so as to cover an exposed surface of the metal post 130 (S160). By filling the inside of the through-hole 124 and the upper surface of the metal post 130 with a solder by way of plating, the solder layer 140, which surrounds the surface of the metal post 130 that is exposed to the outside through the through-hole 124, can be formed.

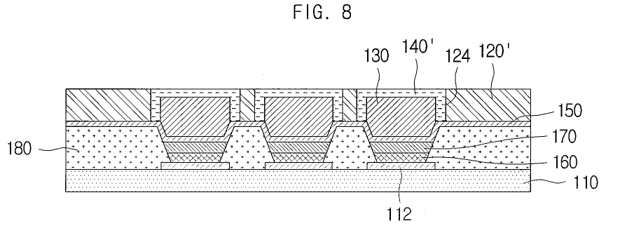

Next, as illustrated in FIG. 8, an upper surface of the solder layer 140′ is flattened such that the upper surface of the solder layer 140′ becomes level (S170). In the previous process, the solder layer 140 may be formed in such a way that the solder layer 140 is protruded from the surface of the resist 120 by setting the plating with enough time. Therefore, in order to make both the upper surface of the solder layer 140 and the surface of the resist 120 flat, a portion of the upper surface of the solder layer 140 can be removed so that the solder layer 140′ with a flattened upper surface can be formed.

As such, by flattening the upper surface of the solder layer 140′, a deviation of plating thickness can be minimized during the plating process of the solder layer 140, and when two or more of bumps are formed, the height of the bumps can be made uniform. Thus, defective interconnection between the printed circuit board 100 and the electronic components caused by a height difference between the bumps can be prevented.

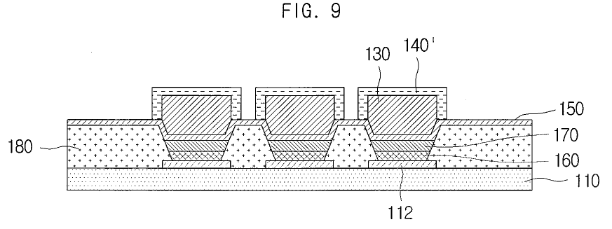

Next, as illustrated in FIG. 9, the resist 120′ is removed (S180). After forming the metal post 130 and the solder layer 140′, the resist 120′ is removed so that the seed layer 150 is exposed to the outside.

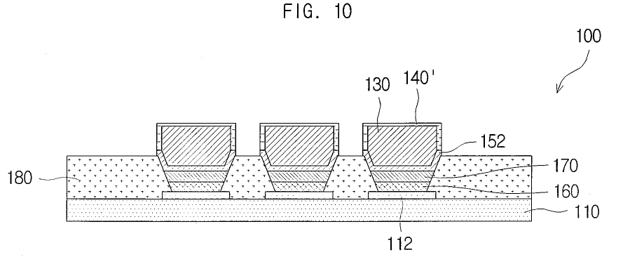

Next, as illustrated in FIG. 10, the exposed seed layer 150 is removed by way of flash etching (S190). In order to prevent a short circuit from occurring between the plurality of bumps, the exposed seed layer 150 is removed by way of flash etching so that the seed layer 150 only remains as the seed 152. Here, with the exposed seed layer 150, a portion of the surface of the solder layer 140′ can be also removed.

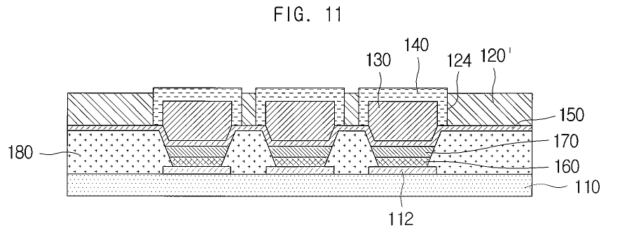

Below, another embodiment of the printed circuit board 100 in accordance with an aspect of the present invention will be described with reference to FIGS. 11 to 14.

FIGS. 11 to 14 show the process flow of a portion of a process for another embodiment of the method of manufacturing the printed circuit board 100 in accordance with an aspect of the present invention.

In the present embodiment, as illustrated in FIG. 2, the substrate 110 having the pad 112 formed thereon is provided (S110), and then the seed layer 150 is formed on the pad 112 (S120). As illustrated in FIGS. 3 and 4, the resist 120′, which has an opening 122 formed therein such that the pad 112 is exposed, is formed on the pad 110 (S130).

Then, as illustrated in FIG. 5, the metal post 130 is formed inside the opening 122 by way of plating such that the metal post 130 is electrically connected to the pad 112 (S140). As illustrated in FIG. 6, by removing a portion of the resist 120′ through the use of a laser, the through-hole 124 is formed in the resist 120′ such that the through-hole 124 surrounds the metal post 130 (S150).

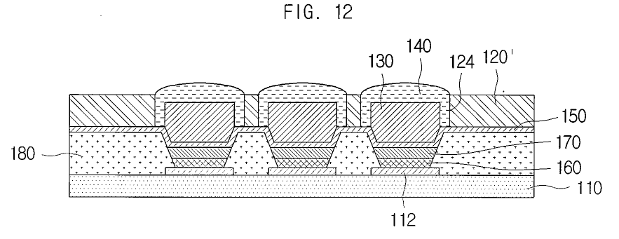

After these processes, as illustrated in FIG. 11, the solder layer 140 is formed inside the through-hole 124 and an upper surface of the metal post 130 so as to cover an exposed surface of the metal post 130 (S160). Then, as illustrated in FIG. 12, a reflow process is performed.

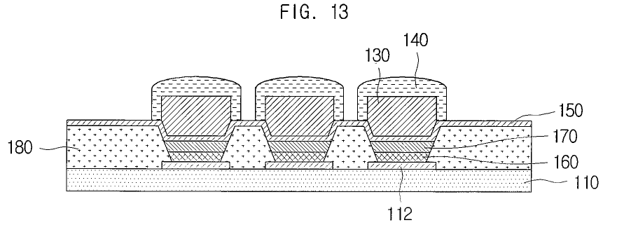

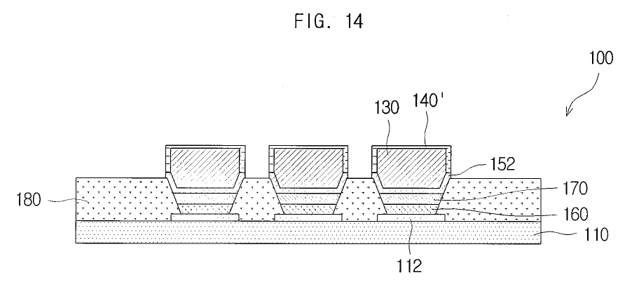

Then, as illustrated in FIG. 13, the resist 120′ is removed (S180). As illustrated in FIG. 14, the exposed seed layer 150 is removed by way of flash etching (S190).

Compared to the previously described embodiment of the present invention, the present embodiment is different in that the solder layer 140 is formed by printing a solder, a process of reflowing the solder layer 140 is performed, and the process of flattening the solder layer 140′ is omitted. Since other processes are the same as or corresponding to the earlier-described embodiment, the difference will be mainly described herein with reference to FIGS. 11 to 14.

Like the previously described embodiment, after the through-hole 124 is formed, the solder layer 140 is formed inside the through-hole 124 and on an upper surface of the metal post 130 so as to cover an exposed surface of the metal post 130 (S160), as illustrated in FIG. 11. That is, unlike the previously described embodiment, the solder layer 140 is formed by printing a solder paste.

Next, as illustrated in FIG. 12, the reflow process is performed. That is, by reflowing the solder layer 140 filling the through-hole 124 by way of printing, the through-hole 124 is completely filled with the solder layer 140 so that the solder layer 140 is in direct contact with the metal post 130 without a void formed in between.

Then, as illustrated in FIG. 13, the resist 120′ is removed (S180). After forming the metal post 130 and the through-hole 124, the resist 120′ is removed so that the seed layer 150 is exposed to the outside.

Then, as illustrated in FIG. 14, the exposed seed layer 150 is removed by way of flash etching (S190). In order to prevent a short circuit from occurring between the plurality of bumps, the exposed seed layer 150 is removed by way of flash etching so that the seed layer 150 only remains as the seed 152. Here, a portion of the surface of the solder layer 140′ is also removed.

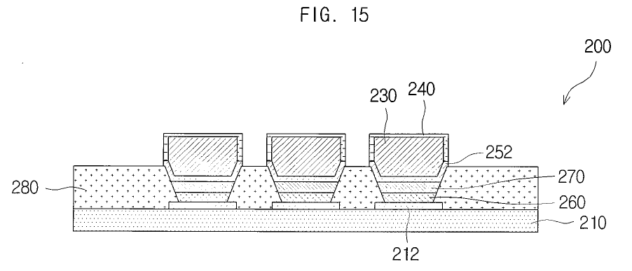

Next, an embodiment of a printed circuit board 200 in accordance with another aspect of the present invention will be described with reference to FIG. 15.

FIG. 15 is a cross-sectional view illustrating an embodiment of the printed circuit board 200 in accordance with another aspect of the present invention.

As illustrated in FIG. 15, the present embodiment provides the printed circuit board 200 that can include a substrate 210 having a pad 212 formed therein, a metal post 230, which is formed on the pad 212 such that the metal post 230 is electrically connected to the pad 212, and a solder layer 240, which is formed on a side of the metal post 230 and an upper surface of the metal post 230 so as to cover an exposed surface of the metal post 230.

According to the present embodiment described above, a bump is constituted by the metal post 230 and the solder layer 240 that surrounds the metal post 230. Thus, when the printed circuit board 200 is coupled together with an electronic component through the flip-chip process, the metal post 230 may function as a core that maintains its shape, and only the solder layer 240 may be reflowed. Therefore, the overall height of the bumps can be prevented from possible height reduction, and at the same time a short circuit between the adjacent bumps can be prevented from occurring when the bump is tilted toward one side.

Furthermore, the metal post 230, unlike the solder layer 240, is made of a low resistance material, such as copper, so that thermal and electrical conductivity can be improved. Therefore, as compared with a bump that is formed by using the conventional solder paste, signal transmission of an electronic component package, heat dissipation and warpage properties can be improved.

Below, each of the components will be described in more detail with reference to FIG. 15.

The substrate 210 can be made of a nonconductive substance, and the pad 212 is formed on the substrate 210, as illustrated in FIG. 15. Moreover, a solder layer 280 can be formed on the surface of the substrate 210, and a portion of the solder layer 280 corresponding to the position of the pad 212 is removed. Then, a nickel layer 260 and a gold layer 270 are successively formed on the pad 212. Additionally, a circuit pattern can be formed on the substrate 210 even though it is not illustrated in the drawings.

The metal post 230 is formed on the pad 212 such that the metal post 230 is electrically connected to the pad 212, as illustrated in FIG. 15. That is, since the nickel layer 260 and the gold layer 270 are successively formed on the pad 212, the metal post 230 can be electrically connected to the pad 212 by forming the metal post 230 on the gold layer 270.

As such, by forming the metal post 230 as a core of a bump, when electronic components and the printed circuit board 200 are coupled together through the flip-chip process, only the solder layer 240 is reflowed. Therefore, the overall height of the bumps can be prevented from possible height reduction, and a short circuit between the bump and its adjacent bumps can be prevented from occurring when the bump is tilted toward one side.

Furthermore, the metal post 230 is made of a low resistance material, such as copper, so that thermal and electrical conductivity can be improved. Therefore, as compared with a bump that is formed by using the conventional solder paste, signal transmission of an electronic component package, heat dissipation and warpage properties can be improved.

The metal post 230 can be formed by first forming the opening (122 of FIG. 4) in the resist (120′ of FIG. 4) formed on the substrate 210 and then filling the inside of the opening (122 of FIG. 4) with a conductive material such as copper. The method of forming the metal post 230 is substantially the same as or similar to that of the embodiment described earlier and thus will not be described again.

The seed 252 is interposed between the pad 212 and the metal post 230, as illustrated in FIG. 15. That is, the seed 252 is used for forming the metal post 230 by way of electroplating, while the seed 252 is formed on the gold layer 270 formed on the pad 212.

As such, while the seed 252 is formed on the pad 212 and used for the electroplating, the metal post 230 can be formed by way of electroplating. Therefore, the rigidity of the metal post 230 can be improved, and at the same time, thermal and electrical conductivity can be further improved.

After forming the metal post 230 on the seed layer (150 of FIG. 8) formed on the pad 212, the seed 252 is a portion that is remained by removing the resist (120′ of FIG. 8) and then flash etching the exposed seed layer (150 of FIG. 8). The method of forming the seed 252 is substantially the same as or similar to that of the embodiment described earlier and thus will not be described again.

The solder layer 240 is formed on a side and an upper surface of the metal post 230 so as to cover an exposed surface of the metal post 230, as illustrated in FIG. 15. That is, while the solder layer 240 is formed in such a way that the solder layer 240 surrounds the metal post 230 as its core, the electronic components and the printed circuit board 200 can be coupled to one another more effectively through the flip-chip process due to the reflowing of the solder layer 240.

Meanwhile, an upper surface of the solder layer 240 is a planar surface, as illustrated in FIG. 15. That is, after forming the solder layer 240 on the metal post 230, the upper surface of the solder layer 240 can be flattened such that the height of the bumps can be made uniform through the flattening process so that a solder layer 240 with uniform height from the substrate 210 can be implemented.

As such, by flattening the upper surface of the solder layer 240, deviation in plating thickness can be minimized during the plating process of the solder layer 240, and when a plurality of bumps are formed, the height of the plurality of bumps can be made uniform. Thus, defective interconnection between the printed circuit board 200 and the electronic components caused by a height difference between the plurality of bumps can be prevented.

After forming the through-hole (124 of FIG. 6) by additionally removing the resist (120′ of FIG. 6), the solder layer 240 is formed inside the through-hole (124 of FIG. 6) and on an upper surface of the metal post 230 by way of plating or printing. The method of forming the solder layer 240 is substantially the same as or similar to that of the embodiment described earlier and thus will not be described again.

While the spirit of the present invention has been described in detail with reference to particular embodiments, the embodiments are for illustrative purposes only and shall not limit the present invention. It is to be appreciated that those skilled in the art can change or modify the embodiments without departing from the scope and spirit of the present invention.

What is claimed is:

1. A method of manufacturing a printed circuit board, the method comprising:
providing a substrate having a pad formed thereon;
forming a resist on the substrate, the resist having an opening formed therein such that the pad is exposed;
forming a metal post inside the opening such that the metal post is electrically connected to the pad;
forming a through-hole in the resist by removing a portion of the resist such that the through-hole surrounds the metal post; and
forming a solder layer inside the through-hole and on an upper surface of the metal post so as to cover an exposed surface of the metal post.

2. The method of claim 1, wherein the forming of the through-hole is performed by a laser.

3. The method of claim 1, wherein the forming of the metal post is performed by way of plating.

4. The method of claim 3 further comprising, prior to the forming of the metal post, forming a seed layer on the pad.

5. The method of claim 1 further comprising, after the forming of the solder layer, flattening an upper surface of the solder layer such that the upper surface of the solder layer becomes level.

6. A printed circuit board comprising:
a substrate having a pad formed therein;
a metal post formed on the pad such that the metal post is electrically connected to the pad;
a solder layer formed on a side of the metal post and an upper surface of the metal post so as to cover an exposed surface of the metal post.

7. The printed circuit board of claim 6, further comprising a seed being interposed between the pad and the metal post.

8. The printed circuit board of claim 6, wherein an upper surface of the solder layer is a planar surface.
